(19) United States
(12) Patent Application Publication
(10) Pub. No.: US 2010/0109098 A1
(43) Pub. Date: May 6, 2010

(54) GATE STRUCTURE INCLUDING MODIFIED HIGH-K GATE DIELECTRIC AND METAL GATE INTERFACE

(75) Inventors: Simon Su-Horng Lin, Hsinchu City (TW); Chi-Ming Yang, Hsin-Chu (TW); Chyi-Shyuan Chern, Taipei (TW); Chin-Hsiang Lin, Hsin-Chu (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/339,990

(22) Filed: Dec. 19, 2008

Related U.S. Application Data
(60) Provisional application No. 61/111,986, filed on Nov. 6, 2008.

(51) Int. Cl. H01L 29/51; H01L 21/3205; H01L 21/4763; H01L 29/49; H01L 21/336

(52) U.S. Cl. 257/411; 438/585; 438/287; 257/E21.409; 257/E21.294; 257/E21.495; 257/E29.16; 257/E29.162

(57) ABSTRACT

A method of fabricating a gate of a semiconductor device is provided. In an embodiment, the method includes forming a gate dielectric layer on a semiconductor substrate. An interface layer is formed on the gate dielectric layer. In an embodiment, the gate dielectric layer includes HfO₂ and the interface layer includes Hf—N. A work function metal layer may be formed on the interface layer. A device is also provided.

### PRIORITY DATA

This application claims priority to Provisional Application Ser. No. 61/111,986 filed on Nov. 6, 2008, entitled “GATE STRUCTURE INCLUDING MODIFIED HIGH-K GATE DIELECTRIC AND METAL GATE INTERFACE”, the entire disclosure of which is incorporated herein by reference.

### BACKGROUND

The present disclosure relates generally an integrated circuit device and, more particularly, a metal gate structure and method of fabrication thereof.

As technology nodes decrease, semiconductor fabrication processes have introduced the use of gate dielectric materials having a high dielectric constant (e.g., high-k dielectrics) to maintain performance. The high-k dielectrics exhibit a higher dielectric constant than the traditionally used silicon dioxide; this allows for thicker dielectric layers to be used to obtain similar equivalent oxide thicknesses (EOTs). The processes also benefit from the introduction of metal gate structures providing a lower resistance than the traditional polysilicon gate structures.

However, the high-k gate structure may lead to a negative shift of the threshold voltage (Vt) of the associated device. The shift may be caused by Fermi-level pinning (FLP), in particular in PMOS devices. FLP is generally identified by oxygen vacancy theory which describes the release of electrons to the p-metal (work function metal of a gate of a PMOS device) which raises the threshold voltage of the p-metal gate and causes FLP.

Therefore, what is needed is an improved gate structure and method of fabrication.

### BRIEF DESCRIPTION OF THE DRAWINGS

FIG. 1 is a flowchart illustrating an embodiment of a method of forming a high-k dielectric metal gate structure.

FIGS. 2, 3, 4, 5 are cross-sectional views of a semiconductor substrate corresponding an embodiment of process steps of the method of FIG. 1.

FIG. 6 is a schematic illustrating a plurality of embodiments of fabricating a metal gate structure.

FIG. 7 is a cross-sectional view of a semiconductor device including a high-k metal gate structure.

### DETAILED DESCRIPTION

The present disclosure relates generally to forming an integrated circuit device and, more particularly, a high-k metal gate structure of a semiconductor device (e.g., a FET device of an integrated circuit). It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Furthermore, included are descriptions of a first layer or feature “on” or “overlying” (as well as similar descriptions) a second layer or feature. These terms include embodiments where the first and second layer are in direct contact and those where one or more layers or feature are interposing the first and second layer. Further still, the exemplary embodiments are for illustrative purposes and not intended to be limiting, for example, numerous configurations of high-k metal gate structures are known in the art, including layers which may or may not be distinctly described herein but would be readily recognizable by one skilled in the art.

Use of high-k gate dielectric and metal gate electrodes, for example, in a PMOS device may include disadvantages. One such disadvantage is Fermi-level pinning induced by oxygen vacancies in the high-k dielectric. An oxygen vacancy induced Fermi level pinning model is described in Modified Oxygen Vacancy Induced Fermi Level Pinning Model Extendable to P-Metal Pinning, by Akasaka et al., which is hereby incorporated by reference. Oxygen may be absorbed by a semiconductor (e.g., silicon) substrate during processing. This may cause electrons to transfer to the metal electrode which causes p-Metal (gate electrode) Fermi level pinning as well as p+ polysilicon pinning. In the referenced article by Akasaka et al, the FLP of p+ poly-silicon is released by inserting a thick silicon oxide layer on both the top and bottom of the high-k dielectric, thus suggesting that the FLP cannot be suppressed without blocking the oxygen transfer both to the electrode as well as the substrate. The thick SiO₂ layers also add to the EOT of an associated device.

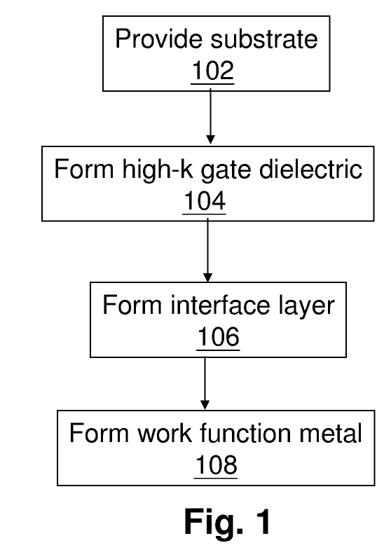

Referring to FIG. 1, illustrated is a flowchart providing an embodiment of a method 100 of forming a gate structure. The method 100 may be included during processing of an integrated circuit, or portion thereof, that may comprise static random access memory (SRAM) and/or other logic circuits, passive components such as resistors, capacitors, and inductors, and active components such as p-channel field effect transistors (PFET), N-channel FET (NFET), metal-oxide semiconductor field effect transistors (MOSFET), complementary metal-oxide semiconductor (CMOS) transistors, bipolar transistors, high voltage transistors, high frequency transistors, other memory cells, combinations thereof, and/or other semiconductor devices.

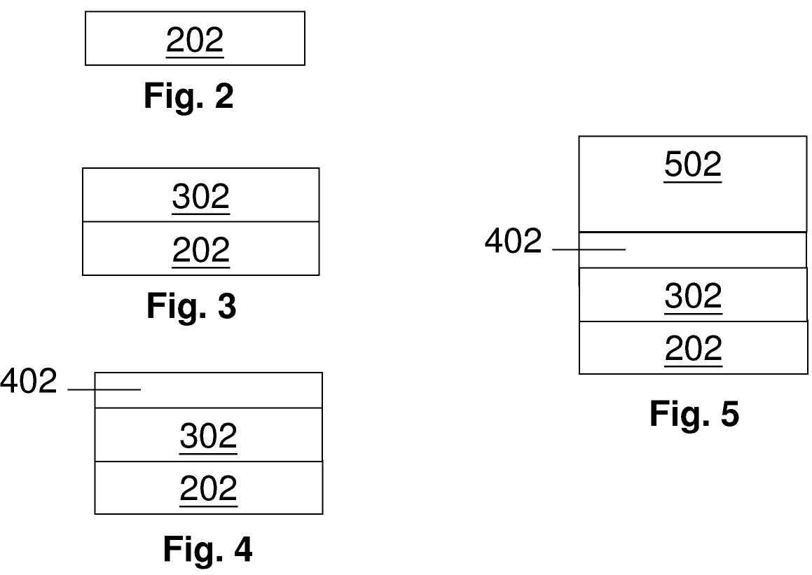

The method 100 begins at step 102 where a substrate (e.g., wafer) is provided. In an embodiment, the substrate includes a silicon substrate in crystalline structure. The substrate may include various doping configurations depending on design requirements as is known in the art (e.g., p-type substrate or n-type substrate) Other examples of the substrate include other elementary semiconductors such as germanium and diamond. Alternatively, the substrate may include a compound semiconductor such as, silicon carbide, gallium arsenide, indium arsenide, or indium phosphide. Further, the substrate may optionally include an epitaxial layer (epi layer), may be strained for performance enhancement, and/or may include a silicon-on-insulator (SOI) structure. Further still, the substrate may include a plurality of features formed thereon, including active regions, source and drain regions in the active regions, isolation regions (e.g., shallow trench isolation (STI) features), and/or other features known in the art. Referring to the example of FIG. 2, a substrate 202 is provided.

The method 100 then proceeds to step 104 where a gate dielectric layer is formed. The gate dielectric layer may include a high-k material (e.g., a material including a “high” dielectric constant, as compared to silicon oxide). Examples of high-k dielectrics include hafnium oxide (HfO₂), hafnium silicon oxide (HfSiO), hafnium silicon oxynitride (HfSiON), hafnium tantalum oxide (HfraO), hafnium titanium oxide (HfriO), hafnium zirconium oxide (HfZrO), combinations thereof, and/or other suitable materials. The formation of the gate dielectric layer may include a plurality of layers including those used in forming an nMOS transistor gate structure and/or a pMOS transistor gate structure. The gate dielectric layer may be formed by atomic layer deposition (ALD). In an embodiment, the thickness of the gate dielectric is between approximately 10 and 30 angstroms (A); this is exemplary only and not intended to be limiting. In an embodiment, the high-k dielectric layer (e.g., HfO₂) is approximately 16 Angstroms (e.g., in a 32 nm technology node process).

Referring to the example of FIG. 3, a high-k dielectric layer 302 is provided. In an embodiment, the high-k dielectric layer 302 is HfO₂. The high-k dielectric layer 302 may be formed by ALD. In an embodiment, the high-k dielectric layer includes an ALD process including sub-cycles of a Hf source pulse and an oxygen source pulse (e.g., HfCl₄ and H₂O respectively) to form an Hf—O layer (e.g., HfOₓ such as HfO₂). The ALD process may include an N₂ carrier gas and be interposed by a purge process(es).

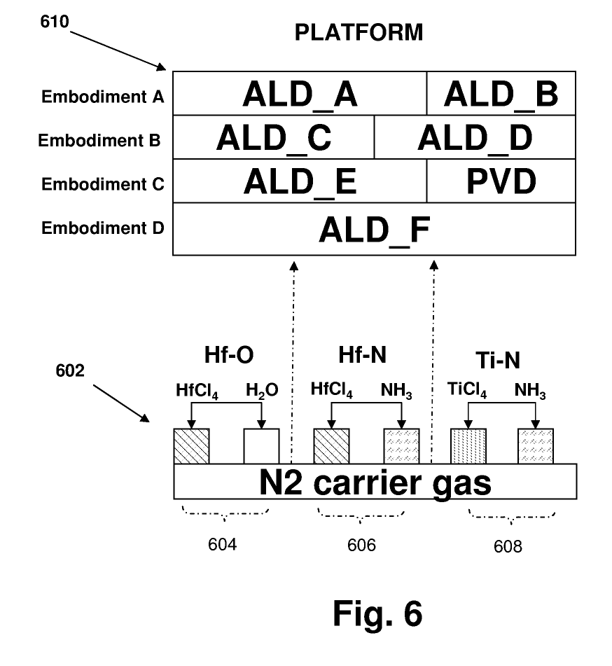

The method 100 then proceeds to step 106 where an interface layer is formed. The interface layer may be formed directly on the high-k dielectric layer. In an embodiment, the interface layer includes hafnium and nitrogen (Hf—N). The interface layer may be less than 6 Angstroms, by way of example and not intended to be limiting. In an embodiment, the interface layer includes 1-3 molecular layers (e.g., as formed in an ALD process). The interface layer may be formed using an ALD process. As described in further detail with reference to FIG. 6, step 106 and step 104 (in whole or in part) may be performed using the same platform or different platforms. The interface layer provides an interface structure between a high-k gate dielectric layer and a subsequently formed layer (e.g., metal gate electrode described below with reference to step 108).

Referring to the example of FIG. 4, an interface layer 402 is formed on the high-k gate dielectric layer 302. In an embodiment, the interface layer 402 may include Hf—N (in any suitable ratio e.g., HfₓN_{y}). The interface layer 402 may be formed using an ALD process. In an embodiment, the interface layer 402 includes an ALD process including sub-cycles of HfCl₄ and NH₃ to form an Hf—N layer. The sub-cycles may include an N₂ carrier gas and be interposed by a purge process. The sub-cycles may be repeated any number of times, in an exemplary embodiment, the cycles are repeated 3 or fewer times to form 3 or fewer molecular layers of an Hf—N composition.

The method 100 then continues to step 108 where a metal gate (e.g., metal gate electrode) may be formed on the substrate. The metal gate includes a metal gate electrode layer providing the work function for the gate structure. The metal gate may provide the work function of a PMOS device. The metal gate may include a p-metal providing such a work function. In an embodiment, the p-metal is TiN. The metal gate layer may be between approximately 50 and 100 Angstroms. The metal gate may be formed using a “gate first” or a “gate last” process (e.g., including a sacrificial polysilicon gate). The metal gate may include one or more layers that when patterned form a metal gate electrode, or portion thereof. The metal gate may include one or more layers including Ti, TiN, TaN, Ta, TaC, TaSiN, W, WN, MoN, MoON, RuO₂, and/or other suitable materials. The metal gate may include one or more layers formed by physical vapor deposition (PVD), CVD, ALD, plating, and/or other suitable processes.

Referring to the example of FIG. 5, a metal gate electrode layer 502 is formed on the interface layer 402. The metal layer 502 may provide the work function of the gate structure. In an embodiment, the metal layer 502 is TiN. The metal layer 502 may be formed using ALD or PVD. In an embodiment, the metal layer 502 is fabricated using an ALD process including sub-cycles of a titanium source pulse (e.g., TiCl₄ pulse) and a nitrogen source pulse (e.g., NH₃ pulse) to form a TiN layer. The sub-cycles may include an N₂ carrier gas and be interposed by a purge process. The sub-cycles may be repeated any number of times to create a layer of any suitable thickness. The metal layer 502 may be formed in the same, or different, ALD process platforms as layers 302 and/or 402 such as described with reference to FIG. 6.

The method 100 may include process steps to provide additional layers in the gate structure (e.g., interfacial layers underlying the high-k dielectric, buffer layers, capping layers), and/or form other features on the substrate such as, interconnects (lines and/or vias), contacts, isolation features, source/drain features, and/or other features known in the art.

The interface layer (structure) provides a modified high-k gate dielectric and metal gate interface. In an embodiment, an interface of Hf—N—Ti is formed. This interface may improve over a conventional Hf—O—Ti provided by a gate dielectric underlying a metal gate electrode (e.g., HfOₓ and TiN layer interface). The interface formed using the method 100 (e.g., Hf—N—Ti) may provide for retarding oxygen diffusion and/or avoid oxygen vacancies. This may be provided by an ALD process with integrated vacuum across the formation of one or more layers described above with reference to steps 104, 106, and 108 such as described with reference to FIG. 6. The platform includes integrated vacuum environment which avoids oxidation of the substrate. One or more embodiments of the method 100 may provide EOT maintenance, FLP reduction, and/or cost savings.

Referring now to FIG. 6, illustrated are a plurality of embodiments of forming a gate structure such as described above with reference to the method 100 of FIG. 1. In particular, FIG. 6 illustrates four embodiments of methods of forming a gate stack. These embodiments are exemplary and not intended to be limiting. Furthermore, FIG. 6 illustrates a formation of gate stack including an Hf—O gate dielectric and a Ti—N work function layer with an Hf—N interface layer interposing Hf—O and Ti—N layers. The provided compositions are exemplary only and not intended to be limiting. One skilled in the art would recognize other gate stacks that may benefit from the disclosed processes. Further still the ALD processes described herein include exemplary compositions of pulses that are also not intended to be limiting.

FIG. 6 includes a description of fabrication of a gate structure including a gate dielectric layer, interface layer, and gate electrode layer. The exemplary embodiment illustrates a gate dielectric layer including hafnium and oxygen (Hf—O), an interface layer including hafnium and nitrogen (Hf—N), and a gate electrode layer including titanium and nitrogen (TiN), however numerous other embodiments are possible. The layers may be substantially similar to the gate dielectric layer 302, interface layer 402, and metal layer 502 respectively, which are described above with reference to FIGS. 1, 3, 4, and 5.

Portion 602 illustrates ALD processes including an ALD process 604 which depicts the formation of a gate dielectric layer (e.g., including Hf—O), an ALD process 606 which depicts the formation of an interface layer (e.g., including Hf—N), and an ALD process 608 which depicts the formation of a metal gate electrode layer (e.g., including Ti—N). Each of the ALD processes may include an N₂ carrier gas (which may also provide for purging the chamber between pulses). As described above, the compositions of pulses provided are exemplary only and one of skill in the art would ready recognize other sources (e.g., of hafnium, oxygen, nitrogen, titanium).

The ALD process 604 (e.g., forming the gate dielectric layer) includes a first pulse including a hafnium source (HfCl₄) and a second pulse including an oxygen source (H₂O). A purge may follow the hafnium source pulse before introducing the oxygen source pulse. A purge may also follow the oxygen source pulse where reaction products and/or excess reactants are purged from the chamber. The first and second pulse of the ALD process 604 may be repeated any number of times.

The ALD process 606 (e.g., forming the interface layer) includes a first pulse including a hafnium source (HfCl₄) and a second pulse including a nitrogen source (NH₃). A purge may follow the hafnium source pulse before introducing the nitrogen source pulse. A purge may follow the nitrogen source pulse where reaction products and/or excess reactants are purged from the chamber. The pulses of the ALD process 606 may be repeated any number of times. As described above, the ALD process 606 may provide an Hf—N layer providing one or more atomic layers.

The ALD process 608 (e.g., forming the metal gate electrode layer) includes a first pulse including a titanium source (TiCl₄) and a second pulse including a nitrogen source (NH₃). A purge may follow the titanium source pulse before introducing the nitrogen pulse. A purge may follow the nitrogen pulse where reaction products and/or excess reactants are purged from the chamber. The pulses of the ALD process 608 may be repeated any number of times to provide a suitable thickness.

Portion 610 of FIG. 6 illustrates a plurality of embodiments denoted A, B, C, and D. These embodiments are exemplary only and not intended to be limiting. The portion 610 illustrates platforms in which the ALD processes 604, 606, and/or 608 may be performed (e.g., processes 604, 606, and 608 may be performed in sequence). A platform may designate a chamber of an ALD tool. A platform may also include multiple chambers of an ALD tool where a substrate may be processed through the multiple chambers without a break (release) in vacuum environment. In other words, a platform includes a tool or portions of a tool where a vacuum environment may be maintained during the processing. Exemplary platforms include ALD tools known in the art under commercial names of EmerALD 3000 and Pulsar 3000.

Embodiment A includes performing the ALD process 604 in a platform ALD_A and the ALD process 606 in the distinct platform ALD_B. Thus, the ALD process 604 and the ALD process 606 are performed without breaking a vacuum environment. Embodiment A provides that the ALD process 608 is performed in a separate platform ALD_B. Therefore, vacuum may be broken between the ALD process 606 and ALD process 608 (or the formation of the interface layer and the metal gate electrode). In an embodiment, of Embodiment A, a chamber is provided where the ALD process 604 is performed. The chamber may include an additional gas line for providing a purge including nitrogen (e.g., NH₃) to perform the ALD process 606 and form an Hf—N layer within the chamber.

Example process conditions of the ALD process 604 applicable to any of Embodiments A, B, C or D include performing the ALD process at approximately 150-300C and 0.1-4 Torr when providing the hafnium and oxygen source pulses of HfCl₄ and H₂O pulses respectively. In an embodiment, these process conditions are also used for the ALD process 606 and/or ALD process 608. In an alternative embodiment, the first pulse of the ALD process 604 includes TEMAH as a hafnium source and O₃ pulse as an oxygen source. The TEMAH and O₃ pulses of the ALD process 604 may be provided at approximately 150-300C and a pressure of approximately 0.1 to 4 Torr. In an embodiment, these process conditions may be used for the ALD processes 606 and/or 608.

Embodiment B includes performing the ALD process 604 in a platform ALD_C and also a portion of the ALD process 606 in the ALD_C platform. The portion of the ALD process 606 performed in the ALD_C platform may include performing one or more cycles of the ALD process 606 (e.g., a hafnium source pulse and a nitrogen source pulse). A portion (e.g., one or more pulses and/or one or more cycles of pulses) of the ALD process 606 and the ALD process 608 are performed in a distinct platform, denoted ALD_D. Therefore, a vacuum environment may be maintained between the ALD process 604 and a portion of the ALD process 606. A vacuum environment may then be broken and the ALD process 606 continued and the ALD process 608 performed in another platform.

Embodiment C includes performing the ALD process 604 and the ALD process 606 in a single ALD platform denoted ALD_E. This may be substantially similar to as described above with reference to Embodiment A. The metal gate electrode layer however, is fabricated using physical vapor deposition (PVD) process. Therefore, a vacuum environment may be broken before the formation of the gate electrode layer.

Embodiment D includes performing the ALD process 604, 606, and 608 all in a single ALD platform denoted ALD_F. In Embodiment D, a vacuum environment may be maintained through-out the formation of a gate dielectric, interface layer, and metal gate electrode layer.

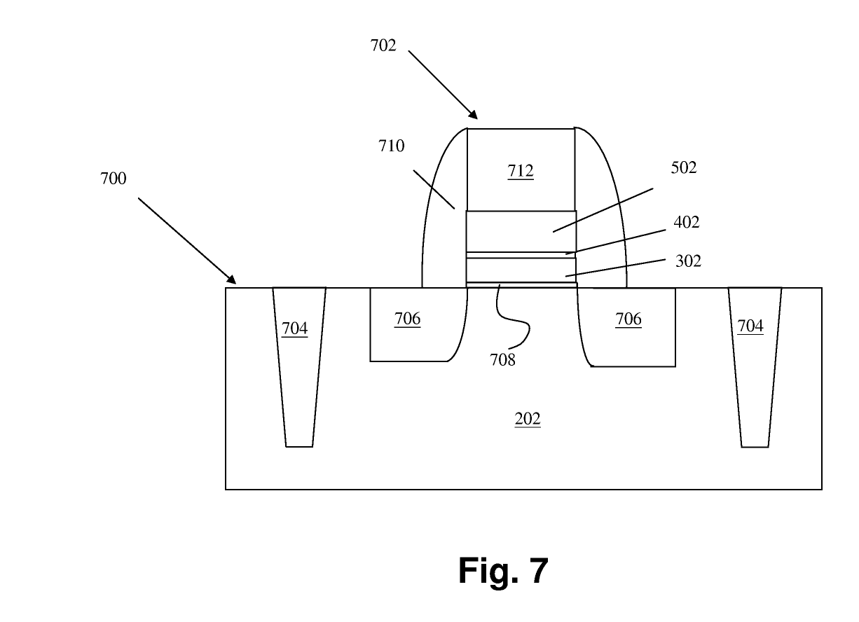

Referring now to FIG. 7, illustrated is a semiconductor device 700. The semiconductor device 700 may be formed using the method 100, described with reference to FIG. 1 respectively. The semiconductor device 700 includes a substrate 202, shallow trench isolation (STI) features 704, source/drain regions 706, spacers 710, and a gate structure 702. Though numerous other embodiments are possible. The gate structure 702 includes an interfacial layer 708, a gate dielectric layer 302, an interface layer 402, a metal gate electrode 502, fill metal 712. However, numerous other configurations of the gate structure 702 are possible including omission of provided layers, and/or addition of one or more layers.

The substrate 202 may be substantially similar to as described above with reference to FIG. 2. The STI features 704 are formed in the substrate 202. The STI features 704 may include silicon oxide, silicon nitride, silicon oxynitride, fluoride-doped silicate glass (FSG), and/or a low-k dielectric material. Other isolation methods and/or features are possible in lieu of or in addition to STI features. The STI features 704 may be formed using processes such as reactive ion etch (RIE) of the substrate 202 to form a trench which is filled with insulator material using deposition processes known in the art, followed by CMP processing. The STI features 704 may define an active region of the substrate 202 in which an nMOS or pMOS device may be formed.

The source/drain regions 706 may include lightly doped source/drain regions and/or heavy doped source/drain regions, and are disposed on the substrate 202 adjacent to (and associated with) the gate structure 702. The source/drain regions 706 may be formed by implanting p-type or n-type dopants or impurities into the substrate 202 depending on the desired transistor configuration. The source/drain features 706 may be formed by methods including photolithography, ion implantation, diffusion, and/or other suitable processes.

The spacers 710 are formed on both sidewalls of the gate structure 702. The spacers 710 may be formed of silicon oxide, silicon nitride, silicon oxynitride, silicon carbide, fluoride-doped silicate glass (FSG), a low-k dielectric material, combinations thereof, and/or other suitable material. The spacers 710 may have a multiple layer structure, for example, including one or more liner layers. The liner layers may include a dielectric material such as silicon oxide, silicon nitride, and/or other suitable materials. The spacers 710 may be formed by methods including deposition of suitable dielectric material and etching the material to form the spacer 710 profile.

The gate structure 702 may be associated with an FET device such as, an nMOS or pMOS device. The interfacial layer 708 includes an oxide composition. The interfacial layer 708 may include silicon, oxygen, and/or nitrogen. In an embodiment, the interfacial layer 708 is SiO₂. The interfacial layer 708 may include a thickness of approximately 5 to 10 angstroms, though various other thicknesses may be suitable. The interfacial layer 708 may be formed by thermal oxidation, atomic layer deposition (ALD), and/or other suitable processes.

The gate dielectric layer 302 may include a high-k dielectric material. In an embodiment, the high-k dielectric material includes hafnium oxide (HfO₂). Other examples of high-k dielectrics include hafnium silicon oxide (HfSiO), hafnium silicon oxynitride (HfSiON), hafnium tantalum oxide (HfTaO), hafnium titanium oxide (HfTiO), hafnium zirconium oxide (HfZrO), combinations thereof, and/or other suitable materials. The high k-gate dielectric layer 302 may be formed by ALD and/or other suitable processes. The gate dielectric layer 302 may be formed as described above with reference to step 104 of the method 100 of FIG. 1 and/or the embodiments of FIG. 6.

The interface layer 402 may be substantially similar to as described above with reference to FIG. 4. For example, in an embodiment, the interface layer is Hf—N. The interface layer 402 may be formed as described above with reference to step 106 of the method 100 of FIG. 1 and/or the embodiments of FIG. 6.

The metal layer 502 may form the metal gate electrode, or portion thereof, of the gate structure 702. The metal layer 502 may include one or more layers including Ti, TiN, TaN, Ta, TaC, TaSiN, W, WN, MoN, MoON, RuO₂, and/or other suitable materials. The metal layer 502 may be formed by physical vapor deposition (PVD), CVD, ALD, plating, and/or other suitable processes. In an embodiment, the metal layer 502 includes a work function metal such that it provides an N-metal work function or P-metal work function of a metal gate. In an embodiment, the metal layer 502 includes a p-metal of TiN. The metal layer 502 may be formed as described above with reference to step 108 of the method 100 of FIG. 1 and/or the embodiments of FIG. 6. The fill metal 712 may be disposed on the metal layer 502 and include one or more liner or wetting layers. In an embodiment, the fill metal layer 712 includes aluminum.

Thus, provided is the semiconductor device 700. The semiconductor device 700 including gate structure 702 includes an interface layer 402 interposing the gate dielectric layer 302 and the metal layer 502. The interface layer 402 may provide an Hf—N—Ti interface. The interface layer 402 may provide for retarding oxygen diffusion and/or avoiding oxygen vacancies.

While the preceding description shows and describes one or more embodiments, it will be understood by those skilled in the art that various changes in form and detail may be made therein without departing from the spirit and scope of the present disclosure. Therefore, the claims should be interpreted in a broad manner, consistent with the present disclosure.

What is claimed is:

1. A method of fabricating a gate of a semiconductor device, comprising:
forming a gate dielectric layer on a semiconductor substrate;
forming a interface layer on the gate dielectric layer; and
forming a work function metal layer on the interface layer.

2. The method of claim 1, wherein the interface layer is formed using an atomic layer deposition process.

3. The method of claim 1, wherein the interface layer includes hafnium and nitrogen.

4. The method of claim 1, wherein the forming the gate dielectric layer is performed in a first atomic layer deposition (ALD) platform and at least a portion of the forming the interface layer is performed in the first ALD platform.

5. The method of claim 4, wherein the entire interface layer is formed in the first ALD platform.

6. The method of claim 4, wherein the work function metal is formed in a second ALD platform.

7. The method of claim 1, wherein the work function metal is formed using a physical vapor deposition (PVD) process.

8. The method of claim 1, wherein forming the interface layer includes an atomic layer deposition (ALD) process including providing a first pulse including HfCl₄ and a second pulse including NH₃.

9. The method of claim 8, wherein the forming the interface layer includes one to three cycles of the first and second pulse.

10. The method of claim 1, wherein the forming the gate dielectric and the forming the interface layer are performed in a vacuum environment where the vacuum environment is not broken between the forming the gate dielectric and the forming the interface layer.

11. A semiconductor device, comprising:
a substrate;
a gate dielectric layer disposed on the substrate, wherein the gate dielectric layer includes a high-k dielectric;
a interface layer disposed on the gate dielectric layer; and
a metal gate electrode disposed on the interface layer.

12. The semiconductor device of claim 11, wherein the gate dielectric layer includes hafnium and oxygen.

13. The semiconductor device of claim 11, wherein the interface layer includes hafnium and nitrogen.

14. The semiconductor device of claim 11, wherein the metal gate electrode includes TiN.

15. The semiconductor device of claim 11, wherein the interface layer is less than approximately 6 angstroms

16. A method comprising:
providing a semiconductor substrate;
forming an interfacial oxide layer on the substrate;
forming a gate dielectric layer using a first atomic layer deposition (ALD) process in a first platform; and
performing a second ALD process, wherein the second ALD process is performed at least in part in the first platform, and wherein the second ALD process includes a first pulse including hafnium and a second pulse including nitrogen.

17. The method of claim 16, wherein the first ALD process includes a third pulse and a fourth pulse, wherein the third pulse includes hafnium and the fourth pulse includes oxygen.

18. The method of claim 16, further comprising:
performing a third ALD process, wherein the third ALD process includes a fifth pulse and a sixth pulse, wherein the fifth pulse includes Ti and the sixth pulse includes nitrogen.

19. The method of claim 16, wherein the second ALD process provides an interface including hafnium, nitrogen, and titanium (Hf—N—Ti).

20. The method of claim 16, wherein the first and the at least a portion of the second ALD processes are performed without breaking a vacuum between the processes.
